(19) United States
(12) Patent Application Publication
(10) Pub. No.: US 2014/0326183 A1
(43) Pub. Date: Nov. 6, 2014

(54) DEPOSITION SOURCE ASSEMBLY

(71) Applicant: Samsung Display Co., Ltd., Yongin-city (KR)

(72) Inventor: Yong-Jun CHA, Yongin-city (KR)

(73) Assignee: Samsung Display Co., Ltd., Yongin-city (KR)

(21) Appl. No.: 14/029,268

(22) Filed: Sep. 17, 2013

(30) Foreign Application Priority Data
May 6, 2013 (KR) 10-2013-0050805

(51) Int. Cl. C23C 16/44

(52) U.S. Cl. CPC C23C 16/4401
USPC 118/722

(57) ABSTRACT

A deposition source assembly for depositing a deposition material on a substrate disposed in a chamber, the deposition source assembly including: a deposition source disposed in the chamber, the deposition source being configured to deposit the deposition material on the substrate; an electrode passing through at least one wall of the chamber, the electrode being configured to provide power to the deposition source; an insulator disposed between the electrode and the wall of the chamber; and an insulator cap disposed on the insulator to cover at least a portion of the insulator.

### CROSS-REFERENCE TO RELATED APPLICATION

This application claims priority from and the benefit of Korean Patent Application No. 10-2013-0050805, filed on May 6, 2013, which is incorporated by reference for all purposes as if set forth herein.

### BACKGROUND

1. Field

Exemplary embodiments relate to a manufacturing technology, and, more particularly, to a deposition source assembly for deposition-based manufacturing techniques that may be utilized in large-substrate mass production processes with enhanced production yield.

2. Discussion

Mobile electric devices, such as mobile phones, notebook computers, personal digital assistants, tablets, etc., typically include a display device for providing a user with visual information, such as an image or video, in order to support a variety of functions. As various components traditionally utilized to interact with the visual information become eliminated or miniaturized (e.g., physical buttons, switches, etc.), the display device itself is becoming of greater importance to mobile electric devices. Furthermore, a display device has been developed to be bendable to a certain angle or extent.

Among conventional display devices, an organic light emitting display device is attractive due, at least in part, to its wide viewing angle, good contrast levels, and fast response times. In general, an organic light emitting display device may be formed by stacking or depositing a variety of layers, which may include a light emitting layer formed of an organic material disposed between a cathode electrode and an anode electrode. Typically, the light emitting layer is disposed on the anode electrode, and the cathode electrode is disposed on the light emitting layer. It is noted that the cathode and anode electrodes and the light emitting layer may be formed by vaporizing and depositing a metal material or organic material. To deposit the metal material or organic material, a crucible is typically utilized, which has a deposition source having a heater installed therein. The heater is utilized to heat the metal or organic material and, thereby, to vaporize the metal or organic material for deposition.

Traditionally, a crucible may include an electrode for supplying power from an external source to heat the heater, as well as include an insulator to insulate the electrode within a chamber of a deposition apparatus. Due, at least in part, to the levels of heat and pressure utilized to effectuate deposition processes, dielectric breakdown may occur in the insulator, which may be intensified when metal material is deposited on the insulator.

The above information disclosed in this Background section is only for enhancement of understanding of the background of the invention, and, therefore, it may contain information that does not form the prior art that is already known in this country to a person of ordinary skill in the art.

### SUMMARY

Exemplary embodiments provide a deposition source assembly that is easily manufactured, may be easily applied to a large-substrate mass production process, and has enhanced production yield and deposition efficiency.

Additional aspects will be set forth in the detailed description which follows and, in part, will be apparent from the disclosure, or may be learned by practice of the invention.

According to exemplary embodiments, a deposition source assembly for depositing a deposition material on a substrate disposed in a chamber, includes: a deposition source disposed in the chamber, the deposition source being configured to deposit the deposition material on the substrate; an electrode passing through at least one wall of the chamber, the electrode being configured to provide power to the deposition source; an insulator disposed between the electrode and the wall of the chamber; and an insulator cap disposed on the insulator to cover at least a portion of the insulator.

According to exemplary embodiments, an apparatus configured to deposit deposition source material on a target substrate, includes: a chamber including: an interior cavity region; and a first aperture extending to the interior cavity region; an insulator disposed in the first aperture, the insulator including a second aperture extending at least to the cavity region; an insulator cap disposed on a distal end of the insulator, the distal end being disposed in the interior cavity region, the insulator cap including a third aperture disposed in association with the second aperture; and an electrode extending into the interior cavity region via the second and third apertures, the electrode being configured to provide power to vaporize the deposition source material.

The foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiments of the invention, and together with the description serve to explain the principles of the invention.

FIG. 1 is a view of a deposition source assembly, according to exemplary embodiments.

FIG. 2 is an enlarged view of a portion A of FIG. 1, according to exemplary embodiments.

FIGS. 3A, 3B, and 3C are views of a variety of shapes of a deposition source cap of the deposition source assembly of FIG. 1, according to exemplary embodiments.

FIG. 4 is a cross-sectional view of an active matrix organic light emitting display device produced using the deposition source assembly of FIG. 1, according to exemplary embodiments.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

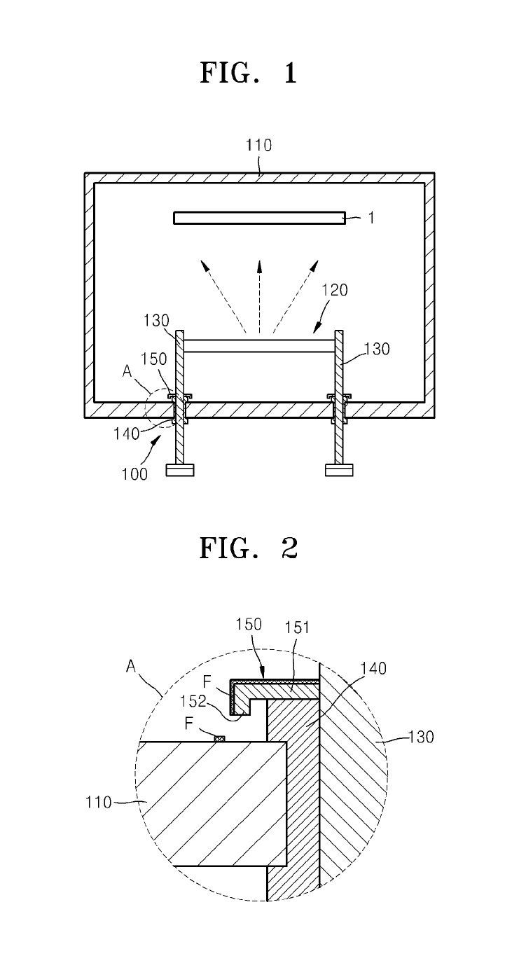

FIG. 1 is a view of a deposition source assembly 100, according to exemplary embodiments. FIG. 2 is an enlarged view of a portion A of FIG. 1.

Referring to FIGS. 1 and 2, the deposition source assembly 100 includes a deposition source 120 disposed in a chamber 110, an electrode 130, an insulator 140, and an insulator cap 150. Although specific reference will be made to this particular implementation, it is also contemplated that the deposition source assembly 100 may embody many forms and include multiple and/or alternative components. For example, it is contemplated that the components of the deposition source assembly 100 may be combined, located in separate structures, and/or separate locations.

A substrate 1 disposed in the chamber 110, which is maintained in a pressurized state (e.g., a vacuum state), may be a substrate for organic light emitting device (OLED) panels. It is contemplated, however, that exemplary embodiments described herein may be implemented to fabricate any suitable substrate upon which one or more metal and/or organic films may be deposited.

According to exemplary embodiments, the deposition source 120 is configured to vaporize a deposition material for deposition onto the substrate 1 to form a thin film on the substrate 1. In particular, the deposition source assembly 100 may be a deposition source assembly for forming a metal film for cathode electrodes. The deposition source assembly 100 for forming a metal film for cathode electrodes of large-scale organic light emitting display devices heats and vaporizes a metal material, such as aluminium (Al), using a heater (not shown). The deposition source assembly 100 is configured to deposit the vaporized metal material on the substrate 1 to form a thin film. To this end, the heater may be configured to reach relatively high temperatures (e.g., over 1300° C.), which is typically utilized to vaporize the material to be deposited. The deposition source 120 may be formed from a metal material, such as, for example, tantalum (Ta), tungsten (W), molybdenum (Mo), etc., and/or a ceramic material, such as pyrolytic boron nitride (PBN), aluminium oxide (AlₓO_{y}), etc., which are stable at the relatively high temperatures used to vaporize the material to be deposited.

The deposition source 120 may use a guide (not illustrated) formed of a ceramic material to support a high temperature heater. In this manner, the deposition source 120 may be fixed (or otherwise coupled to) an electrode 130 in the lower portion of the deposition source 120 to enable stable application of a current to the heater. To this end, the electrode 130 connected to the heater may be kept insulated within chamber 110, which may be formed of any suitable metal material. In this manner, insulation between the chamber 110 and the electrode 130 may be maintained by inserting an insulator 140 between the electrode 130 and the chamber 110.

It is noted that a fume of a metal fine particle generated during a deposition process performed at a high temperature of, for example, 1300° C. or more, may enter a gap caused, at least in part, by allowance for assembly of a top or side portion of the deposition source 120. As such, the fume of the metal fine particle may be deposited on the insulator 140 disposed between the electrode 130 and the chamber 110. This may cause, at least in part, deterioration of the insulation between the electrode 130 and the deposition source 120.

That is, the fume of the deposition material, such as aluminium, generated within the vacuum chamber 110 moves actively at a high temperature and travels in a variety of degrees of freedom. The vaporization of the deposition material may continuously occur within the deposition source 120, and some of the vaporized deposition material may be deposited on an internal component of the deposition source 120. Alternatively, a conductive material used to form the deposition source 120 may be vaporized to be a fume at a high temperature and then deposited on an internal component of the deposition source 120. As such, the conductive material deposited inside the deposition source 120 may deteriorate insulation between the heater (not shown) and the component of the deposition source 120 for supporting the heater, and, in particular, the insulator 140. In this manner, a resistance of the heater may increase and interrupt a flow of current via electrode 130. This may prevent (or otherwise reduce) the proper operation of the heater. In other words, due to the deposited conductive material, the heater may not be able to maintain a high temperature of 1300° C. or more, which is utilized to vaporize a deposition material.

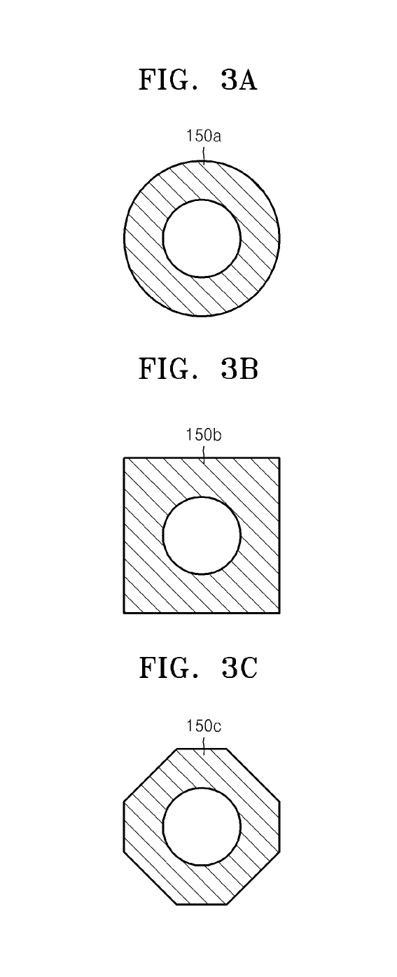

In order to prevent (or otherwise reduce) the deposition of the deposition material on the insulator 140 or between the heater and a component of the deposition source 120, the deposition source assembly 100 may further include an insulator cap 150 of a cap shape. The insulator cap 150 may be disposed on an upper surface of the insulator 140, which may serve to prevent (or otherwise reduce) dielectric breakdown caused, at least in part, by the deposition material being disposed on the insulator 140 or between the heater and a component of the deposition source 120. The configuration and functioning of the insulator cap 150 is described in more detail in association with FIGS. 2 and 3.

It is noted that power may be provided from an external source to heat the deposition source 120 (or power a heater disposed therein). As such, an electrode 130 configured to provide the power to heat the deposition source 120 may be formed to pass through the chamber 110. The electrode 130 may be formed of any suitable conductive member, which may be in the form of a rod (or other suitable configuration) that passes through a bottom surface of the chamber 110. Since the deposition source 120 is disposed within the chamber 110 and a power supply (not shown) is disposed outside the chamber 110, the electrode 130 may deliver electric power received from the power supply to the deposition source 120.

According to exemplary embodiments, the insulator 140 is disposed between the electrode 130 and the chamber 110 and insulates the electrode 130 from the chamber 110. A hole (not shown) through which the electrode 130 may pass is formed at the bottom surface of the chamber 110. In this manner, the insulator 140 may fit into the hole and may extend beyond the hole. The insulator 140 may be formed having a cross-sectional shape of an approximate “I” shape, and may adhere to the inner surface and the outer surface of the chamber 110 to seal the chamber 110. A hole into which the electrode 130 can pass through may be formed in a central portion of the insulator 140. To this end, the insulator 140 is configured to provide insulation between the electrode 130 and the chamber 110 because the electrode 130 passes through the insulator 140, and, thereby, is spaced apart from the chamber 110.

In exemplary embodiments, an insulator cap 150 is formed to cover at least one side of the insulator 140. The insulator cap 150 includes a base 151 that is disposed on the top surface of the insulator 140, and a protrusion portion 152 formed to protrude in at least one direction from the base 151. The protrusion portion 152 is formed to protrude toward the bottom surface of the chamber 110 to reduce the space between the insulator cap 150 and the bottom surface of the chamber 110. This helps to prevent (or reduce) a fume of the deposition material, such as aluminium, that is generated inside the chamber 110, from being deposited on the insulator 140. The insulator cap 150 may be formed such that one end of the protrusion portion 152 of the insulator cap 150 is spaced apart from the chamber 110 by 1 to 5 mm. The insulator cap 150 may be formed of any suitable insulating material, such as, for example, a ceramic material, to protect the insulator 140.

As shown in FIG. 2, the insulator cap 150, according to exemplary embodiments, is configured to prevent (or reduce) a fume F of a conductive deposition material from being deposited on the internal components of the deposition source 120, such as the insulator 140 and the heater (not shown), to keep the internal component insulated, although the fume F of the conductive deposition material may be deposited on respective surfaces of the insulator cap 150 and the chamber 110. If only one of two electrodes 130 is equipped with the insulator cap 150, a conductive material deposited on the surface of the chamber 110 may be also deposited on the surface of the insulator cap 150, which may induce dielectric breakdown. As such, the insulator cap 150 may be utilized in association with each of the insulators 140.

Further, although not illustrated in the drawings, at least a portion of an interior surface of the insulator cap 150 and/or the insulator 140 may be threaded. To this end, at least a portion of the exterior surface of the electrode 130 may also be threaded in a manner to engage the threads of the insulator 140 and/or the insulator cap 150. As such, the threaded engagement of the insulator 140, the insulator cap 150, and/or the electrode 130 may be utilized to further seal an internal region (or cavity) of chamber 110 from an exterior region (or ambient environment) of the chamber 110, and, thereby, enable stable maintenance of a pressurized environment within the interior region of the chamber 110. Further, a hole in the insulator 140 may be concentrically or substantially concentrically aligned with one another.

FIGS. 3A, 3B, and 3C are views of a variety of shapes of the deposition source cap 150 of FIG. 1, according to exemplary embodiments. As illustrated in FIGS. 3A, 3B, and 3C, the insulator cap 150 may have a variety of shapes. An electrode terminal is typically formed by combining a bolt with a nut. In this manner, the electrode terminal may have a round hole formed therein to dispose the electrode between the bolt and the nut. Also, as long as a space is maintained between the insulator 140 and the chamber 110 when disposing the electrode, the insulation cap may have any suitable cross-sectional shape, such as a round cross-sectional insulator cap 150a shown in FIG. 3A, a rectangular cross-sectional insulator cap 150b shown in FIG. 3B, or a polygonal cross-sectional insulator cap 150c shown in FIG. 3C.

According to exemplary embodiments, dielectric properties of the insulator 140 may be prevented (or otherwise reduced) from being deteriorated since a deposition material, such as aluminium, and a metal material forming the deposition source 120, which is vaporized at a high temperature, may be deposited on the insulator cap 150, but not on the insulator 140, and, in this manner, extend the life of the deposition source assembly 100.

Again, the examples of FIGS. 3A, 3B, and 3C are merely illustrative in nature, and, as such, the cross-sectional shape of the insulator cap 150 may be formed in any suitable configuration so long as it retains the function(s) described herein. In this manner, the cross-sectional shape of the insulator cap 150 may correspond to any suitable free-form and/or geometric shape.

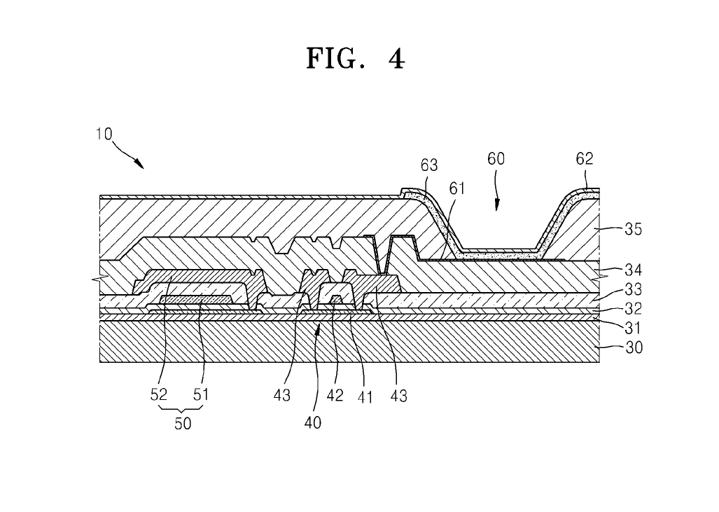

FIG. 4 is a cross-sectional view of an active matrix organic light emitting display device produced using the deposition source assembly 100, according to exemplary embodiments.

Referring to FIG. 4, the active matrix organic light emitting display device 10 is formed on the substrate 30. The substrate 30 may be formed of any suitable transparent material, for example, a glass, plastic, or metal material. An insulation film 31, such as a buffer layer, is formed over the substrate 30.

As shown in FIG. 4, a thin film transistor (TFT) 40, a capacitor 50, and an organic light emitting device 60 are formed on the insulation film 31.

A semiconductor active layer 41, which may be formed or otherwise arranged in a determined pattern, is formed on the insulation film 31. The semiconductor active layer 41 is covered by the gate insulation layer 32. The active layer 41 may be formed of any suitable p-type or n-type semiconductor material.

A gate electrode 42 of the TFT 40 is formed on the gate insulation film 32 and faces the active layer 41. An interlayer dielectric 33 is formed on the gate electrode 42. After forming the interlayer dielectric 33, the gate insulation film 32 and the interlayer dielectric 33 are etched (or otherwise patterned) to form one or more contact holes partially exposing the active layer 41.

Source/drain electrodes 43 are formed on the interlayer dielectric 33 to contact a portion of the active layer 41 that is exposed through the contact holes. A protective film 34 covers the source/drain electrodes 43, and the source/drain electrodes 43 are partially exposed by an etching/patterning process. A separate insulation film (not shown) may be formed on the protective film 34 for the planarization of the protective film 34.

The capacitor 50 includes a first electrode 51 and a second electrode 52. The interlayer dielectric 33 is disposed between the first electrode 51 and the second electrode 52. It is noted that a voltage stored via the capacitor 50 may be provided to one or more electrodes of the TFT 40, e.g., one or more of the gate electrode 42 and the source/drain electrode 43.

The organic light emitting device 60 may be configured to emit any suitable colour, e.g., red, green, blue, etc., light, depending on a current flow and/or materials of the organic light emitting device 60. In this manner, the organic light emitting device 60 may be configured to display determined picture information. The organic light emitting device 60 includes a first electrode 61 disposed on the protective film 34. The first electrode 61 is electrically connected with a drain electrode 43 of the TFT 40.

According to exemplary embodiments, a pixel definition film 35 is formed on the first electrode 61. An opening is formed in the pixel definition film 35 to expose a portion of the first electrode 61. An organic layer 63 including a light emission layer is formed in an area defined by the opening in the pixel definition film 35. A second electrode 62 is formed on the organic layer 63.

The pixel definition film 35 is configured to define each pixel and may be formed of an organic material, which may be configured to planarize the surface of the substrate 30 having the first electrode 61 formed thereon, and, in particular, planarize the surface of the protective film 34.

The first electrode 61 and the second electrode 62 are insulated from each other and apply different polarities of voltages to the organic layer 63 including the light emission layer. In this manner, the light emission layer is configured to emit light of a determined wavelength based on a current imposed on the light emission layer by the different polarities of the voltages.

According to exemplary embodiments, the organic layer 63 including the light emitting layer may be formed of a low or high molecular weight organic material. When a low-molecular weight organic material is used, the organic layer 63 may have a single or multi-layer structure including a hole injection layer (HIL), a hole transport layer (HTL), the light emission layer (EML), an electron transport layer (ETL), and/or an electron injection layer (EIL). For instance, the organic materials may include, for instance, copper phthalocyanine (CuPc), N,N′-di(naphthalene-1-yl)-N,N′-diphenylbenzidine (NPB), tris-8-hydroxyquinoline aluminum (Alq₃), etc.

It is noted that after the organic light emitting film is formed, the second electrode 62 may be formed by the same deposition process.

In exemplary embodiments, the first electrode 61 may function as an anode electrode, and the second electrode 62 may function as a cathode electrode. Alternatively, the first electrode 61 may function as a cathode electrode, and the second electrode 62 may function as an anode electrode. The first electrode 61 may be patterned to correspond to each pixel area, and the second electrode 62 may be formed to cover all pixels. In this manner, the second electrode 62 may serve a common electrode.

The first electrode 61 may be a transparent electrode or reflective electrode. When the first electrode 61 is a transparent electrode, the first electrode 61 may be formed of aluminum zinc oxide (AZO), gallium zinc oxide (GZO), indium tin oxide (ITO), indium zinc oxide (IZO), zinc oxide (ZnO), indium oxide (In₂O₃), etc. It is also contemplated that one or more conductive polymers (ICP) may be utilized, such as, for example, polyaniline, poly(3,4-ethylenedioxythiophene) poly(styrenesulfonate) (PEDOT:PSS), etc. When the first electrode 61 is a reflective electrode, the first electrode 61 may be formed by forming a reflective layer from silver (Ag), magnesium (Mg), aluminum (Al), platinum (Pt), palladium (Pd), gold (Au), nickel (Ni), neodymium (Nd), iridium (Ir), chromium (Cr), etc., or a compound thereof, and forming a layer of AZO, GZO, ITO, IZO, ZnO, In₂O₃, polyaniline, PEDOT:PSS, etc., on the reflective layer. The first electrode 61 may be formed by forming a layer by, for example, sputtering, and then patterned by, for example, photolithography. It is contemplated, however, that any one or more suitable manufacturing techniques may be utilized.

According to exemplary embodiments, the second electrode 62 may be from as a transparent electrode or reflective electrode. When the second electrode 62 is a transparent electrode, the second electrode 62 may be used as a cathode electrode, and, in this manner, may be formed by depositing a metal having a low work function, such as lithium (Li), calcium (Ca), lithium fluoride/calcium (LiF/Ca), lithium fluoride/aluminum (LiF/Al), aluminum (Al), silver (Ag), magnesium (Mg), etc., or a compound thereof, on a surface of the organic layer 63, and forming an auxiliary electrode layer or a bus electrode line thereon from AZO, GZO, ITO, IZO, ZnO, In₂O₃, polyaniline, PEDOT:PSS, or the like. When the second electrode 62 is a reflective electrode, the second electrode 62 may be formed by depositing Li, Ca, LiF/Ca, LiF/Al, Al, Ag, Mg, etc., or a compound thereof on the organic layer 63. In this manner, the deposition may be performed in the same method as used to form the organic layer 63.

In exemplary embodiments, the second electrode 62 may be formed using the deposition source assembly 100 shown in FIG. 1. That is, using the deposition source assembly 100 including a deposition source 120 disposed in a chamber 110 to spray (or otherwise deposit) a deposition material on a target surface, an electrode 130 formed to pass through the chamber 110 to supply power for heating the deposition source 120, an insulator 140 disposed between the electrode 130 and the chamber 110 to block contact therebetween, and an insulator cap 150 formed at one side of the insulator 140 to cover the insulator 140, a deposition material depositing via the deposition source assembly 100 as shown in FIG. 1 may be deposited on a substrate 1 as shown in FIG. 1.

It is also contemplated that the deposition source assembly 100, according to exemplary embodiments, may be used to form a first electrode 61, and also utilized to form one or more others layers from a variety of materials, whether metallic materials or organic materials.

According to exemplary embodiments, a deposition material, such as aluminium, and a metal material forming the deposition source 120 can be vaporized at a high temperature and deposited on an insulator cap 150 protecting the insulator 140, which, thereby, prevents (or otherwise reduces) the potential for dielectric property deterioration. In this manner, the usable life of the deposition source 120 may be extended.

Although certain exemplary embodiments and implementations have been described herein, other embodiments and modifications will be apparent from this description. Accordingly, the invention is not limited to such embodiments, but rather to the broader scope of the presented claims and various obvious modifications and equivalent arrangements.

What is claimed is:

1. A deposition source assembly for depositing a deposition material on a substrate disposed in a chamber, the deposition source assembly comprising:
a deposition source disposed in the chamber, the deposition source being configured to deposit a deposition material on the substrate;
an electrode passing through at least one wall of the chamber, the electrode being configured to provide power to the deposition source;
an insulator disposed between the electrode and the wall of the chamber; and
an insulator cap disposed on the insulator to cover at least a portion of the insulator.

2. The deposition source assembly of claim 1, wherein the deposition source is configured to deposit a metallic material.

3. The deposition source assembly of claim 2, wherein the deposition material comprises at least one of lithium (Li), calcium (Ca), lithium fluoride/calcium (LiF/Ca), lithium fluoride/aluminum (LiF/Al), aluminium (Al), silver (Ag), magnesium Mg, and a compound thereof.

4. The deposition source assembly of claim 1, wherein:
the wall of the chamber comprises an aperture formed therethrough;
the insulator longitudinally extends through the aperture; and
the electrode longitudinally extends through the insulator.

5. The deposition source assembly of claim 4, wherein the insulator is adhered to the inner surface and outer surface of the wall of the chamber.

6. The deposition source assembly of claim 1, wherein the insulator cap comprises:
a base disposed directly on the insulator and longitudinally extending in a first direction; and
a protrusion portion protruding from the base in a second direction.

7. The deposition source assembly of claim 6, wherein the second direction extends toward a bottom surface of the chamber.

8. The deposition source assembly of claim 7, wherein a distal end of the protrusion portion is spaced apart from the bottom surface of the chamber.

9. The deposition source assembly of claim 1, wherein the insulator cap is configured to prevent the deposition material from being deposited on the insulator.

10. The deposition source assembly of claim 1, wherein the insulator cap comprises a ceramic material.

11. An apparatus configured to deposit deposition source material on a target substrate, comprising:
a chamber comprising:
an interior cavity region; and
a first aperture extending to the interior cavity region;
an insulator disposed in the first aperture, the insulator comprising a second aperture extending at least to the cavity region;
an insulator cap disposed on a distal end of the insulator, the distal end being disposed in the interior cavity region, the insulator cap comprising a third aperture disposed in association with the second aperture; and
an electrode extending into the interior cavity region via the second and third apertures, the electrode being configured to provide power to vaporize the deposition source material.

12. The apparatus of claim 11, wherein the deposition source material is a metallic or organic material.

13. The apparatus of claim 12, wherein the deposition source material comprises at least one of lithium (Li), calcium (Ca), lithium fluoride/calcium (LiF/Ca), lithium fluoride/aluminum (LiF/Al), aluminium (Al), silver (Ag), magnesium Mg, and a compound thereof.

14. The apparatus of claim 11, wherein the second and third apertures are substantially concentrically aligned.

15. The apparatus of claim 11, wherein the insulator is coupled to an inner surface of the cavity region and an outer surface of the chamber.

16. The apparatus of claim 11, wherein the insulator cap comprises:
a first portion longitudinally extending away from the electrode in a first direction; and
a second portion protruding from the first portion in a second direction.

17. The apparatus of claim 16, wherein the second direction extends towards a surface of the chamber comprising the first aperture.

18. The apparatus of claim 17, wherein a distal end of the second portion is spaced apart from the surface of the chamber comprising the first aperture.

19. The apparatus of claim 11, wherein the insulator cap is configured to at least limit the amount of vaporized deposition source material deposited on the insulator.

20. The apparatus of claim 11, wherein the insulator cap comprises a ceramic material.
